(19) United States
(12) Patent Application Publication
(10) Pub. No.: US 2025/0252873 A1
(43) Pub. Date: Aug. 7, 2025

(54) RESIN COMPOSITION, AND DISPLAY DEVICE INCLUDING ADHESIVE MEMBER FORMED FROM THE RESIN COMPOSITION

(71) Applicant: Samsung Display Co., Ltd., Yongin-si (KR)

(72) Inventor: Yosuke SAITO, Yokohama (JP)

(21) Appl. No.: 19/022,722

(22) Filed: Jan. 15, 2025

(30) Foreign Application Priority Data
Feb. 6, 2024 (KR) 10-2024-0017783

(51) Int. Cl. G09F 9/30; C08F 2/48; C08F 220/14; C08F 220/18; C08F 220/20; C08F 220/28; C08F 222/10; C08F 230/08; C09J 4/06

(52) U.S. Cl. CPC G09F 9/301; C08F 2/48; C08F 220/14; C08F 220/1808; C08F 220/1811; C08F 220/20; C08F 220/281; C08F 222/1065; C08F 230/08; C09J 4/06; C09J 2203/326; C09J 2301/416; C09J 2433/00

(57) ABSTRACT

A display device includes a display panel, a window arranged on the display panel, and an adhesive member arranged between the display panel and the window, wherein the adhesive member is derived from a resin composition, the resin composition includes a (meth)acrylate oligomer (A) containing a siloxane skeleton, a photo initiator (B), a (meth)acrylate monomer (C) that has a surface tension of about 20 mN/m to about 30 mN/m and is represented by Formula 1 below, and an urethane (meth)acrylate oligomer (D), and a shear viscosity of the resin composition at 25° C. is about 8 mPa·s to 50 mPa·s.

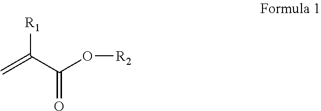

### CROSS-REFERENCE TO RELATED APPLICATION

This application claims priority to and the benefit of Korean Patent Application No. 10-2024-0017783, filed on Feb. 6, 2024, the entire disclosure of which is hereby incorporated by reference.

### BACKGROUND

### 1. Field

The present disclosure herein relates to a resin composition and a display device including an adhesive member formed from the resin composition.

### 2. Description of the Related Art

To provide image information to a user, display devices are used in various multimedia apparatuses, such as televisions, mobile phones, tablet computers, and/or game consoles. Recently, various types (kinds) of flexible display devices, which are foldable, bendable, and/or rollable, have been developed.

The display device is composed of multiple components (e.g., a plurality of members), and includes an adhesive layer for adhering the (e.g., each of) components or members together. The adhesive member employed (e.g., used) in various suitable shapes of display devices may be formed by applying (e.g., depositing) a resin composition (for adhesive) through an inkjet method.

### SUMMARY

An aspect according to one or more embodiments of the present disclosure is directed toward a resin composition with (having) suitable or excellent discharge stability and adhesive strength.

An aspect according to one or more embodiments of the present disclosure is directed toward a display device with (having) suitable or excellent reliability, during performing various suitable operations, by including an adhesive member that is formed from the resin composition, which has a suitable or excellent adhesive strength.

Additional aspects of embodiments will be set forth in part in the description, which follows and, in part, will be apparent from the description, or may be learned by practice of the presented embodiments of the disclosure.

According to one or more embodiments of the disclosure, a display device includes a display panel, a window arranged on the display panel, and an adhesive member arranged between the display panel and the window, wherein the adhesive member is derived from a resin composition, the resin composition includes: a (meth)acrylate oligomer (A) including a siloxane skeleton; a photo initiator (B); a (meth)acrylate monomer (C) including a first monomer that has a surface tension of about 20 mN/m to about 30 mN/m and is represented by Formula 1; and an urethan (meth)acrylate oligomer (D), and the resin composition has a shear viscosity at about 25° C. of about 8 mPa·s to about 50 mPa·s.

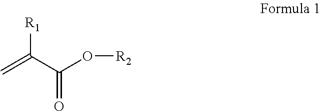

In Formula 1, R₁ is a hydrogen atom, or a substituted or unsubstituted methyl group, and R₂ is a substituted or unsubstituted alkyl group having 1 to 20 carbons.

In an embodiment, the (meth)acrylate oligomer (A) may be synthesized from a first polymerizable monomer represented by Formula 2-1 or Formula 2-2.

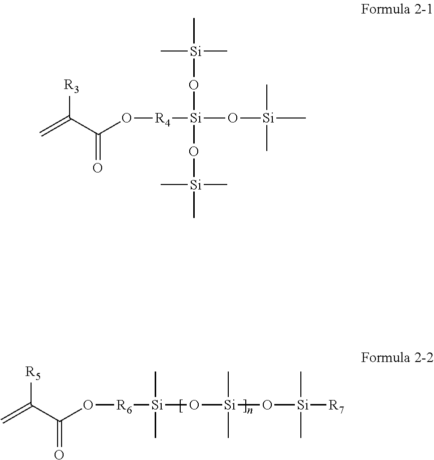

In Formula 2-1 and Formula 2-2, R₃ and R₅ may be each independently a hydrogen atom, or a substituted or unsubstituted methyl group, R₄ and R₆ may be each independently a substituted or unsubstituted alkylene group having 1 to 20 carbons, R₇ may be a substituted or unsubstituted alkyl group having 1 to 20 carbons, and n may be an integer of 0 to 20.

In an embodiment, in Formula 2-1, R₃ may be an unsubstituted methyl group and R₄ may be an unsubstituted n-propylene group, and in Formula 2-2, R₅ may be an unsubstituted methyl group, R₆ may be an unsubstituted n-propylene group and R₇ may be an unsubstituted n-butyl group.

In an embodiment, the (meth)acrylate oligomer (A) may be synthesized from the first polymerizable monomer and a second polymerizable monomer different from the first polymerizable monomer, and the second polymerizable monomer may include at least one selected from among methyl methacrylate, isobornyl methacrylate, and 2-hydroxyethyl methacrylate.

In an embodiment, the first monomer may include 2-ethylhexyl acrylate or isodecyl acrylate.

In an embodiment, the (meth)acrylate monomer (C) may further include a second monomer different from the first monomer, and the second monomer may include at least one selected from among 4-hydroxybutyl acrylate, tetrahydrofurfuryl acrylate, and 2-ethylhexyl diglycol acrylate.

In an embodiment, the resin composition may be a solvent-free composition.

In an embodiment, the (meth)acrylate oligomer (A) may have a weight average molecular weight of about 4,000 to about 20,000.

In an embodiment, the (meth)acrylate monomer (C) may have a weight average molecular weight of about 400 to about 1,500.

In an embodiment, the urethane (meth)acrylate oligomer (D) may have a weight average molecular weight of about 8,000 to about 50,000.

In an embodiment, based on a total 100 weight percent (100 wt %) of the resin composition, the (meth)acrylate oligomer (A) may be about 1 wt % to about 7 wt % in amount, the photo initiator (B) may be about 1 wt % to about 5 wt % in amount, the (meth)acrylate monomer (C) may be about 50 wt % to about 90 wt % in amount, and the urethane (meth)acrylate oligomer (D) may be about 1 wt % to about 15 wt % in amount.

In an embodiment, the photo initiator (B) may include a radical polymerizable initiator.

In an embodiment, the adhesive member may have a storage modulus at −20° C. of about 0.2 MPa or less.

In an embodiment, the adhesive member may have a 180° peel strength of about 800 gf/25 mm or greater for a glass substrate or a polyethylene terephthalate (PET) film at 25° C.

In an embodiment, the adhesive member may be formed by directly depositing the resin composition onto a surface of the window or a surface of the display panel and then UV curing the resin composition.

In an embodiment, the display device may further include an input sensing part, wherein the adhesive member may be arranged between the display panel and the input sensing part or between the input sensing part and the window.

In an embodiment, the display panel may include a display element layer and an encapsulation layer arranged on the display element layer, the input sensing part may be directly arranged on the encapsulation layer, and the adhesive member may be arranged on the input sensing part.

In an embodiment, the display device may further include an optical control layer arranged between the adhesive member and the window, and an optical adhesive layer arranged between the optical control layer and the window, wherein the optical adhesive layer may include a polymer derived from the resin composition.

In an embodiment, the display device may include at least one folding axis, and at least a portion of the display device may be folded with respect to the folding axis.

According to one or more embodiments of the disclosure, a resin composition includes a (meth)acrylate oligomer (A) including a siloxane skeleton, a photo initiator (B), a (meth)acrylate monomer (C) including a first monomer that has a surface tension of about 20 mN/m to about 30 mN/m and is represented by Formula 1, and a urethane (meth)acrylate oligomer (D), wherein the resin composition has a shear viscosity at 25° C. of about 8 mPa·s to 50 mPa·s.

### BRIEF DESCRIPTION OF THE DRAWINGS

The accompanying drawings are included to provide a further understanding of the disclosure, and are incorporated in and constitute a part of this specification.

The drawings illustrate embodiments of the disclosure and, together with the description, serve to explain principles of the disclosure. In the drawings:

FIG. 1 is a combined perspective view illustrating an unfolded state of a display device according to an embodiment of the disclosure;

FIG. 2A is a combined perspective view illustrating an in-folded state of a display device according to an embodiment of the disclosure;

FIG. 2B is a combined perspective view illustrating an out-folded state of a display device according to an embodiment of the disclosure;

FIG. 3 is an exploded perspective view of a display device according to an embodiment of the disclosure;

FIG. 4 is a cross-sectional view of a display device according to an embodiment of the disclosure;

FIG. 5A to FIG. 5C are each a cross-sectional view schematically showing a (e.g., one) step (e.g., task or act) of a method of manufacturing an adhesive member according to an embodiment of the disclosure;

FIG. 6A and FIG. 6B are each a cross-sectional view schematically showing a (e.g., one) step (e.g., task or act) of a method of manufacturing an adhesive member according to an embodiment of the disclosure;

FIG. 7 is a cross-sectional view illustrating a display device according to an embodiment of the disclosure; and

FIG. 8 is a cross-sectional view illustrating a display device according to an embodiment of the disclosure.

### DETAILED DESCRIPTION

In the disclosure, various suitable modifications may be made and various suitable forms may be applied, and specific embodiments will be illustrated in the drawings and described in more detail in the text. However, this is not intended to limit the scope of the disclosure to any specific disclosed form. It should be understood that the scope of the present disclosure is to include all suitable changes, equivalents, and substitutes included in the spirit and scope of the disclosure.

As used herein, it will be understood that when an element (region, layer, or part) is referred to as being “on”, “connected to” or “coupled to” another element, it can be directly on, connected, or coupled to the another element or intervening components may be present.

In contrast, in this application, when an element is referred to as being “directly arranged on” other layers, membranes, regions, or plates, there are no intervening layers, membranes, regions, or plates present. For example, “directly arranged on” or “directly on” may refer to that two layers or two members are directly arranged (e.g., in direct contact with each other) without using an additional intervening member, such as an adhesive member.

Like reference numerals or symbols refer to like elements throughout. In addition, in the drawings, the thickness, the ratio, and the dimension of the elements may be exaggerated for effective descriptions of the technical contents.

The term “and/or” includes any and all combinations of one or more of the associated listed items.

It will be understood that, although the terms such as first, and second, may be used to describe various elements, these elements should not be limited by these terms. These terms are only used to distinguish one element from other elements. For example, a first element could be referred to as a second element, and similarly, the second element could be referred to as the first element without departing from the scope of the disclosure. The singular forms are intended to include the plural forms as well unless the context clearly indicates otherwise.

In addition, the terms, such as “beneath”, “below”, “above”, and “upper”, are used herein to describe the relationship between components as illustrated in the drawings. These terms are relative concepts and are described according to the orientation depicted in the drawings. In the specification, the term “arranged on” and/or the like can refer to not only a case where a member is arranged on an upper part of another member but also a case where the member is arranged on a lower part of the other member.

It will be further understood that the terms “include” or “have” when used in this specification, specifies the presence of stated features, integers, steps, operations, components, parts, or combinations thereof but do not preclude the presence or addition of one or more other features, integers, steps, operations, parts or combinations thereof.

As used herein, the term “substituted or unsubstituted” may refer to a functional group that is substituted or unsubstituted with one or more substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the example substituents may be substituted or unsubstituted. For example, a biphenyl group may be interpreted as an aryl group, or a phenyl group substituted with a phenyl group.

In the description, the alkyl group may be a linear, branched or ring type or kind. The carbon number of the alkyl group may be 1 to 60, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like. However, an embodiment of the disclosure is not limited thereto.

In the description, a cycloalkyl group may refer to a cyclic alkyl group. The carbon number in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like. However, an embodiment of the disclosure is not limited thereto.

In the description, the same explanation on the above-described alkyl group may be applied to an alkylene group except that the alkylene group is a divalent group.

In the description, an alkenyl group refers to a hydrocarbon group including one or more carbon double bonds in the middle and/or at the terminal end of an alkyl group having a carbon number of 2 or more. The alkenyl group may be a linear chain or a branched chain. The carbon number is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, and/or the like. However, an embodiment of the disclosure is not limited thereto.

In the description, an aryl group refer to any functional group or substituent derived from an aromatic hydrocarbon ring. The aryl group may be a monocyclic aryl group or a polycyclic aryl group. The ring-forming carbon number in the aryl group may be 6 to 30, 6 to 20, or 6 to 15. Examples of the aryl group may include a phenyl group, a naphthyl group, a fluorene group, an anthracene group, a phenanthrene group, a biphenyl group, a terphenyl group, a quaterphenyl group, a quinquephenyl group, a sexiphenyl group, a triphenylenyl group, a pyrenyl group, a benzofluoranthene group, a chrysene group, and/or the like. However, an embodiment of the disclosure is not limited thereto.

In the description, a fluorenyl group may be substituted, and two substituents may be combined with each other to form a spiro structure. Examples of a substituted fluorenyl group are as follows. However, an embodiment of the disclosure is not limited thereto.

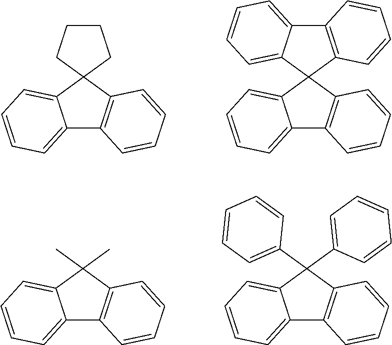

In the description, a heterocyclic group refers to any functional group or substituent derived from a ring including one or more from among B, O, N, P, Si, and S as ring-forming heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

In the description, a heteroaryl group may include one or more from among B, O, N, P, Si, and S as ring-forming heteroatoms. If the heteroaryl group includes two or more heteroatoms, the two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyridine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like. However, an embodiment of the disclosure is not limited thereto.

In the description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the description, a silyl group includes an alkyl silyl group and an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like. However, an embodiment of the disclosure is not limited thereto.

In the description, a thio group may include an alkyl thio group and an aryl thio group. The thio group may refer to the above-defined alkyl group or aryl group combined with a sulfur atom. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like. However, an embodiment of the disclosure is not limited thereto.

In the description, an oxy group may refer to the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not specifically limited but may be, for example, 1 to 20 or 1 to 10. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and/or the like. However, an embodiment of the disclosure is not limited thereto.

In the description, a boron group may refer to the above-defined alkyl group or aryl group, combined with a boron atom. The boron group includes an alkyl boron group and an aryl boron group. Examples of the boron group may include a dimethylboron group, a diethylboron group, a t-butylmethylboron group, a diphenylboron group, a phenylboron group, and/or the like. However, an embodiment of the disclosure is not limited thereto.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a resin composition according to an embodiment of the disclosure and a display device including an adhesive member formed from the resin composition will be explained in more detail with reference to the accompanying drawings.

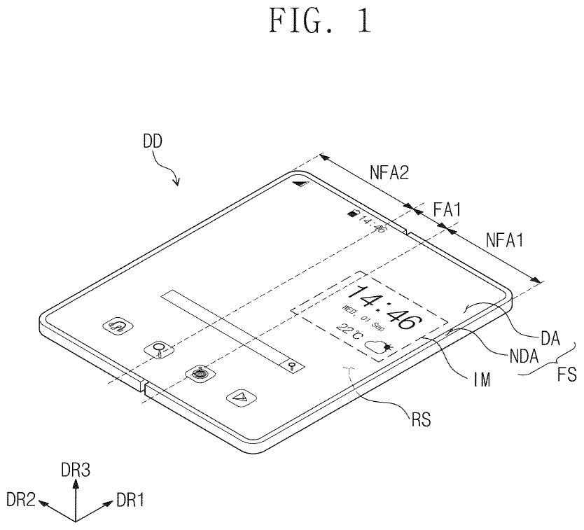

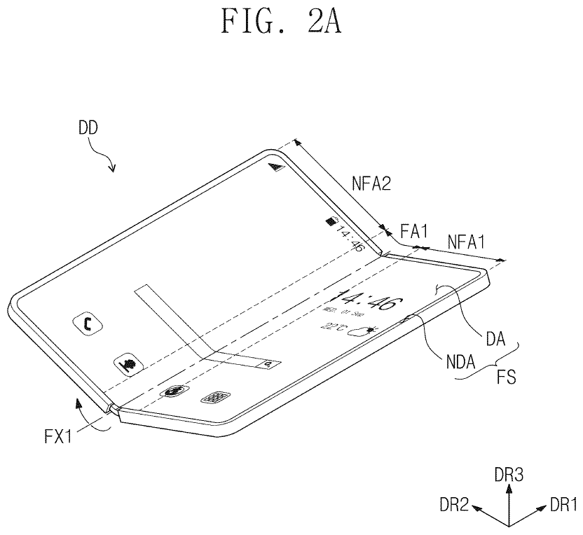

FIG. 1 is a combined perspective view illustrating an unfolded state of a display device DD according to an embodiment of the disclosure. FIG. 2A is a combined perspective view illustrating an in-folded state of the display device DD according to an embodiment of the disclosure. FIG. 2B is a combined perspective view illustrating an out-folded state of the display device DD according to an embodiment of the disclosure.

The display device DD according to an embodiment of the disclosure, illustrated in FIG. 1, is activated in response to an electrical signal. For example, the display device DD may be a mobile phone, a tablet computer, a monitor, a television, a car navigation system, a game console, or a wearable device, but an embodiment of the disclosure is not limited thereto. In FIG. 1, the display device DD is illustrated as a mobile phone as an example. The display device DD according to an embodiment may be a flexible display device capable of being folded, bent, and/or rolled.

In FIG. 1 and the other drawings, a first direction DR1, a second direction DR2, and a third direction DR3 are illustrated, and directions indicated by the first direction DR1, the second direction DR2, and the third direction DR3 described herein may be relative concepts and thus may be changed into other directions. As used herein, the first direction DR1 and the second direction DR2 are perpendicular to each other, and the third direction DR3 is a normal direction with respect to a plane defined by the first direction DR1 and the second direction DR2.

As used herein, a thickness direction of the display device DD may be parallel to the third direction DR3, which is a normal direction with respect to the plane defined by the first direction DR1 and the second direction DR2. A front surface (or an upper surface) and a rear surface (or a lower surface) of members constituting the display device DD may be defined with respect to the third direction DR3.

As used herein, the term “on a plane” or “in a plan view” may refer to being viewed from a plane parallel to the plane defined by the first direction DR1 and the second direction DR2. As used herein, the term “overlap” may refer to overlapping on a plane or in a plan view (of the display device DD) unless defined otherwise.

Referring to FIG. 1, the display device DD may display an image IM through a display surface FS. The display surface FS may include a display region DA and a non-display region NDA. The display region DA may be a region activated in response to an electrical signal. The display device DD may display an image IM through the display region DA. In addition, in the display region DA, various types or kinds of external inputs may be detected. The non-display region NDA may be adjacent to the display region DA. The non-display region NDA may be around (e.g., surround) the display region DA. Therefore, a shape of the display region DA may be substantially defined by the non-display region NDA. However, this is illustrated as an example, and the non-display region NDA may be arranged adjacent to only one side of the display region DA, or may not be provided. The display surface FS may include a plane defined by the first direction DR1 and the second direction DR2.

A rear surface RS of the display device DD may face the display surface FS. In one or more embodiments, because the rear surface RS is an outer surface of the display device DD, a video or an image may not be displayed thereon. In one or more embodiments, the rear surface RS may function as a second display surface on which a video or an image is displayed.

The display device DD may be divided into a folding region FA1 and non-folding regions NFA1 and NFA2. In addition, in the display device DD, the non-folding regions NFA1 and NFA2 may be defined in plural. A first non-folding region NFA1 and a second non-folding region NFA2 may be spaced and/or apart (e.g., spaced apart or separated) with the folding region FA1 therebetween.

In FIG. 1 to FIG. 2B, the display device DD including one folding region FA1 is illustrated, but this is illustrated as an example, and in one or more embodiments, in the display device DD, a plurality of folding regions may be defined. In addition, the display device DD may be folded with respect to a plurality of folding axes, such that some portions of the display surface FS are thus opposed to (e.g., facing or facing oppositely away from) each other. The number of the folding axes and the number of the non-folding regions corresponding thereto, which are included in the display device DD, are not limited to any one embodiment.

Referring to FIG. 2A and FIG. 2B, the display device DD may be folded with respect to the first folding axis FX1. The first folding axis FX1 illustrated in FIG. 2A and FIG. 2B is a virtual axis extending in the first direction DR1, and the first folding axis FX1 may be parallel to a long side direction of the display device DD. However, this is illustrated as an example, and the extending direction of the first folding axis FX1 is not limited to the first direction DR1.

The first folding axis FX1 may extend along the first direction DR1 on the display surface FS or may extend along the first direction DR1 on the rear surface (or bottom surface) RS. Referring to FIG. 2A, the first non-folding region NFA1 and the second non-folding region NFA2 face each other, and the display device DD may be in-folded such that the display surface FS is not exposed to the outside. Referring to FIG. 2B, the display device DD may be folded with respect to the first folding axis FX1 and may be transformed into the out-folded state in which, on the rear surface RS, one region overlapping the first non-folding region NFA1 and the other region overlapping the second non-folding region NFA2 face each other.

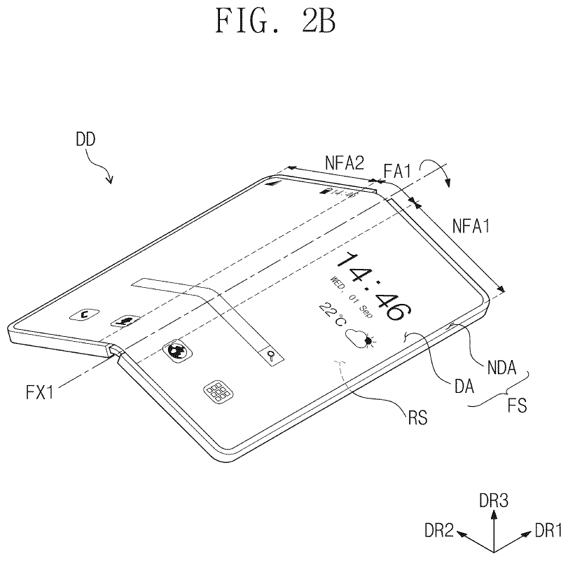

FIG. 3 is an exploded perspective view of the display device DD according to an embodiment of the disclosure.

Referring FIG. 3, the display device DD includes a display module DM, a window WP on the display module DM, and an adhesive member AP arranged between the display module DM and the window WP. In addition, the display device DD may further include a support member SM arranged below the display module DM, a protection layer PF arranged on the window WP, and a housing HAU accommodating the display module DM, the support member SM, and/or the like.

The housing HAU may contain a material having relatively high rigidity. For example, the housing HAU may include a plurality of frames and/or plates composed of glasses, plastics, and/or metals. The housing HAU may provide a set or predetermined accommodating space. The display module DM may be accommodated in the accommodating space to be thus protected from an external impact.

The support member SM may include a metal material and/or a polymer material. For example, the support member SM may include stainless steel, aluminum, or an alloy thereof. In one or more embodiments, the support member SM may include carbon fiber reinforced plastic (CFRP), and/or the like. However, an embodiment of the disclosure is not limited thereto, and the support member SM may include a non-metal material, plastic, and/or glass fiber reinforced plastic or glass.

In one or more embodiments, the display device DD may further include a cushion layer, a blocking layer, and/or the like, arranged below the support member SM. The cushion layer may include an elastomer such as sponge, foam, and/or a urethane resin. The blocking layer may be an electromagnetic wave blocking layer and/or a heat dissipation layer.

The display module DM may be activated in response to an electrical signal. The display module DM may display an image IM (FIG. 1) by being activated in the display region DA (FIG. 1) of the display device DD. In the display module DM, an active region AA-DM and a peripheral region NAA-DM may be defined. The active region AA-DM may be activated in response to an electrical signal. The peripheral region NAA-DM may be located adjacent to at least one side of the active region AA-DM. In the peripheral region NAA-DM, a circuit, a wire, and/or the like for driving the active region AA-DM may be arranged.

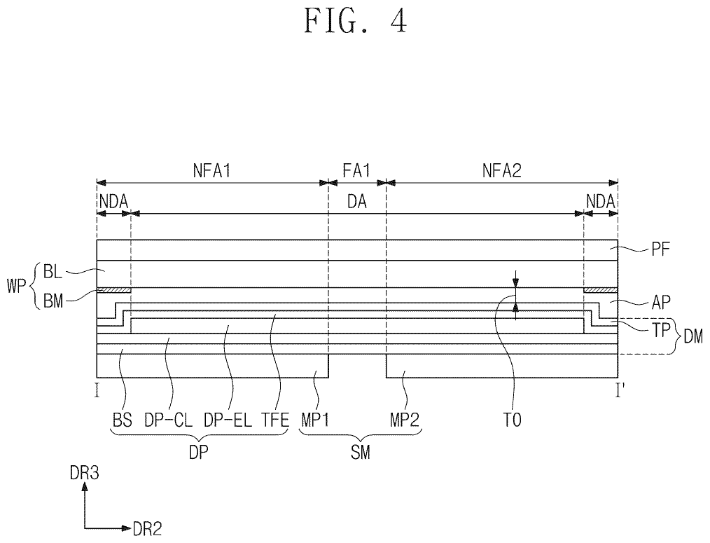

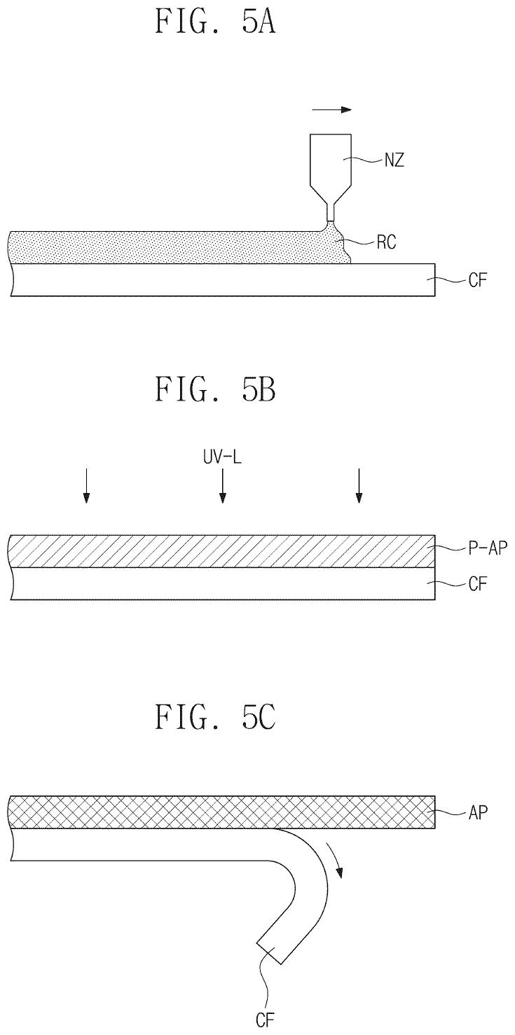

The adhesive member (e.g., adhesive layer) AP may be arranged on the display module DM. The display module DM may be coupled with the window WP by the adhesive member AP. The adhesive member AP may be optically transparent. The adhesive member AP according to an embodiment may include a polymer derived from a resin composition RC according to an embodiment (see FIG. 5A and FIG. 6A). The adhesive member AP may be formed from the resin composition RC according to an embodiment. The adhesive member AP formed from the resin composition RC according to an embodiment may exhibit suitable or excellent adhesion reliability. In an embodiment, the display device DD including the adhesive member AP formed from the resin composition RC may exhibit suitable or excellent reliability during performing an operation such as folding, bending, and/or rolling.

The window WP may include a glass substrate. The window WP may protect the display module DM, and/or the like. A generated image IM (FIG. 1) in the display module may be provided to the user through the window WP. For example, the window WP may include an ultra-thin glass (UTG).

The window WP may include a transmission region TA and a bezel region BZA. The transmission region TA may overlap at least a portion of the active region AA-DM of the display module DM. The transmission region TA may be optically transparent. The image IM (FIG. 1) may be provided to the user through the transmission region TA.

The bezel region BZA may be a region having relatively lower light transmittance than the transmission region TA. The bezel region BZA may define a shape of the transmission region TA. The bezel region BZA may be adjacent to the transmission region TA, and may be around (e.g., surround) the transmission region TA.

The bezel region BZA may have a set or predetermined color. The bezel region BZA may cover the peripheral region NAA-DM of the display module DM, and thus may block the peripheral region NAA-DM from being viewed from the outside. However, an embodiment of the disclosure is not limited thereto, and the bezel region BZA may be arranged adjacent to only one side of the transmission region TA, or at least a portion thereof may not be provided.

The protection layer PF may be a functional layer protecting one side (for example, a top surface) of the window WP. The protection layer PF may include an anti-fingerprint coating agent, a hard coating agent, an antistatic agent, and/or the like.

In one or more embodiments, an auxiliary adhesive layer may be arranged between the window WP and the protection layer PF. In one or more embodiments, the protection layer PF may not be provided.

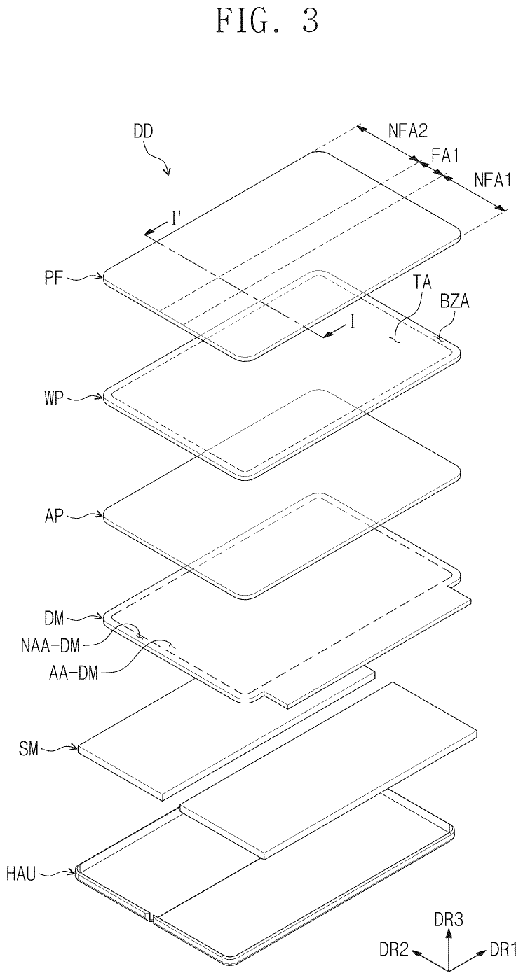

FIG. 4 is a cross-sectional view of the display device according to an embodiment of the disclosure. FIG. 4 may be a cross-sectional view taken along the line I-I′ in FIG. 3.

In FIG. 4, for ease of the description, among the configurations in FIG. 3, the housing HAU is not provided, and only the support member SM, the display module DM, the adhesive member AP, the window WP, and the protection layer PF are illustrated.

Referring to FIG. 4, the support member SM may include a first support part MP1 overlapping the first non-folding region NFA1, and a second support part MP2 overlapping the second non-folding region NFA2. The first support part MP1, and the second support part MP2 may be spaced and/or apart (e.g., spaced apart or separated) in the folding region FA1. In one or more embodiments, the first support part MP1 and the second support part MP2 may not overlap the folding region FA1. In one or more embodiments, at least a portion of the first support part MP1 and at least a portion of the second support part MP2 may overlap the folding region FA1.

The display module DM may include a display panel DP and an input sensing part TP arranged on the display panel DP. The display panel DP may include a base substrate BS, a circuit layer DP-CL arranged on the base substrate BS, a display element layer DP-EL arranged on the circuit layer DP-CL, and an encapsulation layer TFE arranged to cover the display element layer DP-EL.

The configuration of the display panel DP illustrated in FIG. 4, is shown as an example, and the configuration of the display panel DP is not limited thereto. For example, the display panel DP may include a liquid display element, and in this case, the encapsulation layer TFE may not be provided.

The base substrate BS may provide a base surface in which the circuit layer DP-CL is arranged. The base substrate BS may be a flexible substrate capable of being bent, folded, rolled, and/or the like. The base substrate BS may be a glass substrate, a metal substrate, a polymer substrate, and/or the like. However, an embodiment of the disclosure is not limited thereto, and the base substrate BS may include an inorganic layer, an organic layer, or a complex material layer (e.g., an organic-inorganic composite material layer).

The circuit layer DP-CL may include an insulation layer, a semiconductor pattern, a conductive pattern, a signal line, and/or the like. For example, the circuit layer DP-CL may include a switching transistor and a driving transistor for driving a light-emitting element in the display element layer DP-EL.

The display element layer DP-EL may include a light-emitting element for emitting light. For example, the display element may be an organic light-emitting element, an inorganic light-emitting element, an organic-inorganic light-emitting element, a micro LED, a nano LED, a quantum dot light-emitting element, an electrophoretic element, an electrowetting element, and/or the like.

The encapsulation layer TFE may be arranged on the display element layer DP-EL. The encapsulation layer TFE may protect the display element layer DP-EL from moisture, oxygen, and/or foreign substances such as dust particles. The encapsulation layer TFE may include at least one inorganic layer. In one or more embodiments, the encapsulation layer TFE may include at least one organic layer and at least one inorganic layer. For example, the encapsulation layer TFE may include an inorganic layer, an organic layer, and an inorganic layer, sequentially stacked.

The input sensing part TP may be arranged on the display panel DP. For example, the input sensing part TP may be directly arranged on the encapsulation layer TFE. The input sensing part TP may detect an external input, convert into a set or predetermined input signal, and provide the input signal to the display panel DP. For example, in the display device DD according to an embodiment, the input sensing part TP may be a touch sensing part that detects a touch. The input sensing part TP may recognize a direct touch by the user, an indirect touch by the user, a direct touch by an object, an indirect touch by an object, and/or the like.

The input sensing part TP may detect at least any one from among a location and intensity (pressure) of the touch applied from the outside. In an embodiment, the input sensing part TP may have various suitable structures and/or may be composed of various suitable materials, but the disclosure is not limited thereto. The input sensing part TP may include a plurality of sensing electrodes for detecting an external input. The sensing electrodes may detect an input from the outside by a capacitance method. In the display panel DP, an input signal may be provided from the input sensing part TP, and an image corresponding to the input signal may be generated.

The window WP may include a base layer BL and a print layer BM. In one or more embodiments, the base layer BL may be a glass substrate. In one or more embodiments, the base layer BL may be a plastic substrate. For example, the base layer BL may include polyimide, polyacrylate, polymethylmethacrylate, polycarbonate, polyethylene naphthalate, polyvinylidene chloride, polyvinylidene difluoride, polystyrene, an ethylene vinyl alcohol copolymer, or a combination thereof.

The print layer BM may be arranged on one surface of the base layer BL. The print layer BM may be provided in at least a partial region of a bottom surface of the base layer BL that is adjacent to the display module DM. The print layer BM may be arranged at an edge region of the base layer BL. The print layer BM may be an ink-printed layer. In addition, the print layer BM may be a layer formed including a pigment and/or a dye. In the window WP, the bezel region BZA may be a part in which the print layer BM is provided.

The adhesive member AP may be arranged between the display module DM and the window WP. The adhesive member AP may have a thickness TO of about 50 μm to about 200 μm. For example, the adhesive member AP may have the thickness TO of about 50 μm to about 100 μm. However, these thicknesses are disclosed as an example, and the thickness TO of the adhesive member AP is not limited thereto.

The adhesive member AP according to an embodiment includes a polymer derived from a resin composition RC (see FIG. 5A and FIG. 6A) according to an embodiment, which will be described in more detail later. The resin composition RC according to an embodiment includes at least one (meth)acrylate oligomer, at least one photo initiator, at least one (meth)acrylate monomer, and at least one urethane (meth)acrylate oligomer. The resin composition RC according to an embodiment will be described later in more detail.

As to be described in more detail later, because the adhesive member AP according to an embodiment has a high peel strength under moist heat (e.g., hot and humid) environment, the adhesive member AP according to an embodiment may exhibit suitable or excellent adhesion reliability and folding reliability. The humid heat (e.g., hot and humid) environment may refer to an environment of high temperature and humidity. Even in humid heat (e.g., hot and humid) environment, because the adhesive member AP is not peeled from an adherend (for example, the display module DM or the window WP), an operation such as folding or unfolding may be easily performed. That is, the display device DD including the adhesive member AP according to an embodiment may exhibit suitable or excellent reliability during performing an operation such as folding and unfolding even in the humid heat (e.g., hot and humid) environment, because the adhesive member does not detach from the adherend in such an environment.

FIG. 5A to FIG. 5C are each a cross-sectional view schematically illustrating a step of a method of manufacturing the adhesive member AP according to an embodiment of the disclosure.

The method of manufacturing the adhesive member AP according to an embodiment may include: providing the resin composition RC onto the substrate CF (e.g., to form a preliminary adhesive member P-AP); forming the adhesive member AP by providing light (e.g., UV light or UV-L) to the preliminary adhesive member P-AP; and releasing the adhesive member AP from the substrate CF.

FIG. 5A is a cross-sectional view showing an example of the providing of the resin composition RC onto the substrate CF. Referring to FIG. 5A, the resin composition RC may be applied onto the substrate CF. The resin composition RC may be applied onto the substrate CF through a nozzle NZ. For example, the substrate CF on which the resin composition RC is provided may include polyethylene terephthalate (PET). The substrate CF is a temporary substrate used for forming the adhesive member AP from the resin composition RC. Therefore, any suitable substrate that is capable of being easily released from the adhesive member AP after curing of the resin composition RC may be used without limitation. A release treatment is performed on one surface of the substrate CF on which the resin composition RC is provided.

The resin composition RC may be provided by an inkjet printing method or a dispensing method. The resin composition RC according to an embodiment may have a shear viscosity of about 8 mPa-s to about 50 mPa-s, as measured in accordance with JIS Z8803 standards. The shear viscosity is measured at about 25° C. and at about 10 rpm. If (e.g., when) the shear viscosity of the resin composition RC falls within the above-described range, the resin composition RC may exhibit suitable or excellent discharge stability. That is, if (e.g., when) the shear viscosity of the resin composition RC falls within the above-described range, the resin composition RC may be easily discharged from a device such as a nozzle NZ, and may be applied in a uniform amount and at a uniform thickness so as not to deviate from (e.g., the topography of) the member on which the resin composition RC is to be provided. For example, if (e.g., when) the shear viscosity of the resin composition RC falls within the above-described range, the resin composition RC may be easily discharged from a device such as a nozzle NZ, and may be applied in a uniform amount and at a uniform thickness over a surface of the member on which the resin composition RC is provided.

The resin composition RC according to an embodiment may include no solvent (e.g., exclude any solvents). The resin composition RC according to an embodiment may include no volatile organic solvent (e.g., exclude any volatile organic solvents). The resin composition RC may be provided as a solvent-free composition. Because the resin composition RC is the solvent-free composition, discharge of the resin composition RC from the nozzle NZ may be made easier. If (e.g., when) the resin composition RC includes the volatile organic solvent, a heat process for drying the volatile organic solvent, and/or the like may be included in processes for manufacturing an adhesive member containing the resin composition RC, which may make the discharge of the resin composition from the nozzle NZ more difficult.

The resin composition RC according to an embodiment is a photocurable resin composition. The resin composition RC according to an embodiment may be an UV photocurable resin that is cured by UV. The resin composition RC according to an embodiment is in a liquid state before curing (before being cured), and may be cross-linked or cured when being irradiated with light such as UV.

The resin composition RC according to an embodiment may include a (meth)acrylate oligomer (A) (e.g., at least one (meth)acrylate oligomer (A)), a photo initiator (B), a (meth)acrylate monomer (C), and a urethane (meth)acrylate oligomer (D).

The (meth)acrylate oligomer (A) according to embodiment has a siloxane skeleton. The (meth)acrylate oligomer (A) may be synthesized from a first polymerizable monomer. The (meth)acrylate oligomer (A) may be derived from a first polymerizable monomer represented by Formula 2-1 or Formula 2-2 below.

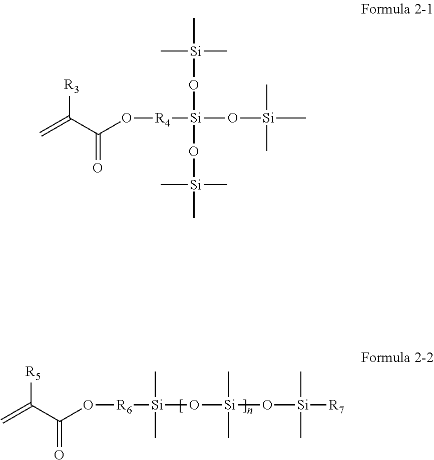

In Formula 2-1 and Formula 2-2, R₃ and R₅ may be each independently a hydrogen atom, or a substituted or unsubstituted methyl group. For example, R₃ and R₅ may be each an unsubstituted methyl group.

In Formula 2-1 and Formula 2-2, R₄ and R₆ may be each independently a substituted or unsubstituted alkylene group having a carbon number of 1 to 20. R₄ and R₆ may be each independently a substituted or unsubstituted linear chain alkylene group having a carbon number of 1 to 20, or a substituted or unsubstituted branched chain alkylene group having a carbon number of 1 to 20. For example, R₄ and R₆ may each be an unsubstituted n-propylene group.

In Formula 2-2, R₇ may be a substituted or unsubstituted alkyl group having a carbon number of 2 to 20. R₇ may be a substituted or unsubstituted linear chain alkyl group having a carbon number of 1 to 20, or a substituted or unsubstituted branched chain alkyl group having a carbon number of 1 to 20. For example, R₇ may be an unsubstituted n-butyl group.

In Formula 2-2, n may be an integer of 0 to 20. For example, n may be 1.

In an embodiment, a (meth)acrylate oligomer (A) may be a polymer, which is synthesized from a first polymerizable monomer and a second polymerizable monomer different from the first polymerizable monomer. The second polymerizable monomer may include at least one from among methyl methacrylate, isobornyl methacrylate, and 2-hydroxyethyl methacrylate. For example, the second polymerizable monomer may include all of methyl methacrylate, isobornyl methacrylate, and 2-hydroxyethyl methacrylate. For example, the (meth)acrylate oligomer (A) may be an oligomer synthesized from reacting the first polymerizable monomer represented by Formula 2-1 or Formula 2-2 with the second polymerizable monomer which is at least one selected from among methyl methacrylate, isobornyl methacrylate, and 2-hydroxyethyl methacrylate.

The (meth)acrylate oligomer (A) may have a weight average molecular weight of about 4,000 to about 20,000. For example, in an embodiment, the (meth)acrylate oligomer (A) may have a weight average molecular weight of about 8,000 to about 9,500. Because the resin composition RC includes the (meth)acrylate oligomer (A) having the weight average molecular weight in the above-described ranges, the resin composition RC may be easily discharged from the nozzle NZ and may be applied in a uniform amount and at a uniform thickness (e.g., on the substrate CF).

With respect to the total weight of the resin composition RC (e.g., 100 wt %), a weight percentage of the (meth)acrylate oligomer (A) may be about 1 wt % to about 20 wt %. Because an amount of the (meth)acrylate oligomer (A) included in the resin composition falls within the above-described range, the resin composition RC may have an appropriate shear viscosity, which makes it easier to discharge the resin composition RC from the nozzle NZ, and thus the resin composition RC may be provided by an inkjet printing method or a dispensing method. In addition, because the amount of (meth)acrylate polymer (A) included in the resin composition RC falls within the above-described range, the adhesive member AP formed from the resin composition RC may have a suitable or excellent adhesive strength, and may be easily folded or unfolded (e.g., without being detached from an adherent by the folding and unfolding).

The resin composition RC includes at least one photo initiator (B). The photo initiator (B) may include a radical polymerizable initiator. When the resin composition RC includes a plurality of photo initiators (B), the different photo initiators may be activated by light (e.g., UV) having different peak wavelengths.

For example, the photo initiator (B) may include at least one from among 2,2-dimethoxy-1,2-diphenylethan-1-one, 1-hydroxy cyclohexyl-phenyl ketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-one.

In addition, the photo initiator (B) may include at least one from among 2-methyl-1-[4-(methylthio)phenyl]-2-morpholinopropan-1-one), 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenylbis(2,4,6-trimethylbenzoyl) phosphine oxide, [1-(4-phenylsulfanylbenzoyl)heptylideneamino]benzoate, [1-[9-ethyl-6-(2-methylbenzoyl) carbazol-3-yl]ethylideneamino]acetate, and bis(2,4-cyclopentadienyl)bis [2,6-difluoro-3-(1-pyrryl)phenyl]titanium (IV).

With respect to the total weight of the resin composition RC (e.g., a total of 100 weight percent (100 wt %)), the photo initiator (B) may have a weight percentage of about 1 wt % to about 10 wt %. For example, with respect to the total weight of the resin composition RC, the weight percentage of the photo initiator (B) may be about 1 wt % to about 5 wt %. However, the weight percentage is suggested as an example, and the weight (e.g., amount) of the photo initiator (B) is not limited to thereto.

The resin composition RC includes at least one (meth)acrylate monomer (C). In an embodiment, the (meth)acrylate monomer (C) may include a (meth)acryloyl group. As used herein, the term “(meth)acryloyl group” refers to an acryloyl group or a methacryloyl group, and the term “(meth)acryl” refers to acryl or methacryl. For example, the (meth)acrylate monomer may be an acrylate monomer or a methacrylate monomer including one acryloyl group or one methacryloyl group.

The (meth)acrylate monomer (C) includes a first monomer. The first monomer included in the (meth)acrylate monomer (C) is represented by Formula 1 below.

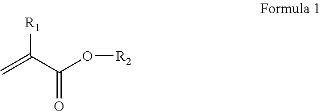

In Formula 1, R₁ may be a hydrogen atom, or a substituted or unsubstituted methyl group. For example, R₁ may be an unsubstituted methyl group.

In Formula 1, R₂ may be a substituted or unsubstituted alkyl group having a carbon number of 1 to 20. For example, R₂ may be any one from among a 4-hydroxybutyl group, a 2-ethylhexyl group, a tetrahydrofurfuryl group, and a 2-ethylhexyl diglycol group.

The first monomer included in the (meth)acrylate monomer (C) may include 2-ethylhexyl acrylate, or isodecyl acrylate.

The first monomer included in the (meth)acrylate monomer (C) may have a surface tension of about 20 mN/m to about 30 mN/m. Because the surface tension of the first monomer is about 20 mN/m to about 30 mN/m, the resin composition RC may be easily discharged from the nozzle NZ, and may be applied in a uniform amount and at a uniform thickness. If (e.g., when) the first monomer has a surface tension of less than about 20 mN/m, the adhesive member formed from the resin composition RC may have reduced application uniformity on a polyethylene terephthalate film. If (e.g., when) the first monomer has a surface tension of more than about 30 mN/m, the discharge of the resin composition RC from the nozzle NZ may be difficult. The resin composition RC according to an embodiment may include two or more (meth)acrylate monomers (C). The (meth)acrylate monomer (C) may include the above-described first monomer and may further a second monomer different from the first monomer. The second monomer may include at least one from among 4-hydroxybutyl acrylate, tetrahydrofurfuryl acrylate), and 2-ethylhexyl diglycol acrylate. For example, the resin composition RC according to an embodiment may include, as the first monomer, 2-ethylhexyl acrylate, and may include, as the second monomer, all of 4-hydroxybutyl acrylate, tetrahydrofurfuryl acrylate, and 2-ethylhexyl diglycol acrylate. In an embodiment, the resin composition RC according to an embodiment may include, as the first monomer, isodecyl acrylate and may include, as the second monomer, all of 4-hydroxybutyl acrylate, tetrahydrofurfuryl acrylate, and 2-ethylhexyl diglycol acrylate. However, an embodiment of the disclosure is not limited thereto.

With respect to the total weight of the resin composition (e.g., 100 wt %), a weight percentage of the (meth)acrylate monomer (C) may be about 50 wt % to about 90 wt %. For example, with respect to the total weight of the resin composition, the weight percentage of the (meth)acrylate monomer (C) may be about 80 wt % to about 90 wt %. With respect to the total weight of the resin composition, if (e.g., when) the weight percentage of the (meth)acrylate monomer (C) is less than about 50 wt %, a cross-linking (e.g., excessive cross-linking) occurs in the resin composition, and thus tack (e.g., adhesion) characteristics of the surface may decrease. Therefore, a peel strength of the adhesive member formed from the resin composition on a glass substrate may decrease. With respect to the total weight of the resin composition, if (e.g., when) the weight percentage of the (meth)acrylate monomer (C) is more than about 90 wt %, a cross-linking does not sufficiently occur in the resin composition, and thus cohesion may be insufficient or even disappear. Therefore, the adhesive member formed from the resin composition may have a decreased peel strength on the glass substrate. That is, when the weight percentage of the (meth)acrylate monomer (C) is less than about 50 wt %, the resin composition may be excessively cross-linked and may lead to decreased adhesion. Also, when the weight percentage of the (meth)acrylate monomer (C) is more than about 90 wt %, the resin composition may have insufficient cross-linking and may lead to insufficient cohesion. In both cases, the adhesive member formed from the resin composition may have a decreased peel strength on the glass substrate.

When the resin composition RC includes two or more (meth)acrylate monomers (C), with respect to the total weight of the resin composition RC (e.g., 100 wt %), the sum of the weight percentages of the two or more (meth)acrylate monomers (C) (e.g., the total amount of all the (meth)acrylate monomers (C)) may be about 50 wt % to about 90 wt %. Because the total amount of the (meth)acrylate monomer (C) included in the resin composition RC falls within the above-described range, the resin composition may have an appropriate shear viscosity, which makes it easier to discharge the resin composition RC from the nozzle NZ, and thus the resin composition RC may be suitably deposited by an inkjet printing method, or a dispensing method. In addition, if (e.g., when) the amount of (meth)acrylate monomers (C) (e.g., total amount in case of two or more (meth)acrylate monomers (C)) included in the resin composition RC falls within the above-described range, the adhesive member AP formed from the resin composition RC may have a suitable or excellent adhesive strength, and may be easily folded and unfolded.

The resin composition RC includes at least one urethane (meth)acrylate oligomer (D). For example, the resin composition RC may include one urethane acrylate oligomer, or the resin composition RC may include two or more urethane oligomers having different weight average molecular weights.

In an embodiment, the urethane (meth)acrylate oligomer (D) may have a weight average molecular weight of about 5,000 to about 40,000. Because the urethane (meth)acrylate oligomer (D) having the weight average molecular weight of about 5,000 to about 40,000 is included in the resin composition RC in an oligomer state having a relatively high degree of polymerization, the resin composition may maintain a high degree of polymerization after curing, and thus may form the adhesive member AP having suitable or excellent adhesion reliability.

With respect to the total weight of the resin composition RC (e.g., 100 wt %), a weight percentage of the urethane (meth)acrylate oligomer (D) may be about 1 wt % to about 40 wt %. In one or more embodiments, with respect to the total weight of the resin composition RC (e.g., 100 wt %), the weight percentage of the urethane (meth)acrylate oligomer (D) may be about 1 wt % to about 15 wt %. For example, with respect to the total weight of the resin composition RC (e.g., 100 wt %), the weight percentage of the urethane (meth)acrylate oligomer (D) may be about 4 wt %. However, these weight percentages are disclosed as examples, and the weight (e.g., amount) of the urethane (meth)acrylate oligomer (D) is not limited thereto.

FIG. 5B is a cross-sectional view showing as example the forming of an adhesive member AP by providing light to the resin composition RC. Referring to FIG. 5B, UV-L (e.g., UV light) may be irradiated to a preliminary adhesive member P-AP formed by applying of the resin composition RC at a uniform thickness on the substrate CF. FIG. 5B illustrates that UV-L is directly irradiated on the preliminary adhesive member P-AP, but an embodiment of the disclosure is not limited thereto. A carrier film may be arranged on the preliminary adhesive member P-AP, and the carrier film may cover the preliminary adhesive member P-AP during a curing process. The carrier film may transmit UV-L.

Referring to FIG. 5A and FIG. 5B, the UV-L may be provided, under a presence of oxygen (e.g., in an oxygen-containing atmosphere), to the preliminary adhesive member P-AP. The adhesive member AP (see FIG. 5C) according to an embodiment may be formed by curing the resin composition RC according to an embodiment under the presence of oxygen. The UV-L may be provided once, or may be provided two or more times in order to form the adhesive member AP from the resin composition RC. For example, when UV-L is provided twice in order to form the adhesive member AP from the resin composition RC, the applied resin composition RC is pre-cured by providing (e.g., a first dose of) UV-L (e.g., to the resin composition RC to form the pre-cured resin composition), and final curing may be achieved by providing (e.g., a second dose of) UV-L to the pre-cured resin composition. The resin composition RC may be finally cured to form the adhesive member AP (see FIG. 5A).

FIG. 5C may be a cross-sectional view showing the releasing of the adhesive member AP from the substrate CF. FIG. 5C illustrates that the substrate CF is released from the adhesive member AP formed by providing UV-L (see FIG. 5B) to the preliminary adhesive member P-AP (see FIG. 5B).

Referring to FIG. 5A and FIG. 5C, the adhesive member AP formed, under a presence of oxygen, by curing the resin composition RC according to an embodiment may have a 180° peel strength of 800 gf/25 mm to about 2,000 gf/25 mm at about 25° C. for a glass substrate. For example, the adhesive member AP according to an embodiment may have a 180° peel strength of 1,000 gf/25 mm to about 1,500 gf/25 mm at about 25° C. for a glass substrate. If (e.g., when) the related art curable resin composition is cured under the presence of oxygen in the air, the polymerization reaction of the resin composition is inhibited due to the presence of oxygen. Therefore, the adhesive member formed by curing the related art resin composition under the presence of oxygen has low adhesion. Even though the resin composition RC according to an embodiment is cured under the presence of oxygen, the resin composition RC according to an embodiment includes the (meth)acrylate oligomer (A), the photo initiator (B), the (meth)acrylate monomer (C), and the urethane (meth)acrylate oligomer (D), as described above, and thus may form an adhesive member AP having suitable or excellent adhesion reliability. That is, in an embodiment, the adhesive member AP according to the disclosure may exhibit a suitable or excellent peel strength in a humid heat (e.g., hot and humid) environment, even when the adhesive member AP is photocured under the presence of oxygen.

The adhesive member AP formed by curing the resin composition RC according to an embodiment may have a storage modulus (G′) at −20° C. of about 0.01 MPa to about 0.2 MPa. In an embodiment, the resin composition RC has a low storage modulus (G′) even when photocured, and thus may exhibit suitable or excellent adhesion reliability. Therefore, in the adhesive member AP formed from the resin composition RC, a lifting phenomenon does not occur at an interface, and thus folding and unfolding may be easily carried out. That is, the adhesive member AP formed from the resin composition RC remains securely bonded to an adherent, and thus folding and unfolding may be easily and reliably carried out.

The released adhesive member AP may be provided on one surface of the window WP or one surface of the display module DM (see FIG. 4). For example, one surface of the adhesive member AP is laminated on a surface of the window WP or on a surface of the display module DM, and a surface of the display module DM or a surface of the window WP, which is not laminated with the adhesive member AP, may be adhered to the other surface of the adhesive member AP.

FIG. 6A and FIG. 6B are each a cross-sectional view schematically showing a step of a method of manufacturing the adhesive member AP according to an embodiment of the disclosure.

FIG. 6A and FIG. 6B are cross-sectional views for explaining different manufacturing methods from the method of manufacturing the adhesive member AP, which is described with reference to FIG. 5A to FIG. 5C. In the descriptions of FIGS. 6A and 6B, duplicated contents as the contents described with reference to FIGS. 1 to 5C will not be explained again, and a difference will be mainly described.

Referring to FIG. 6A, the resin composition RC may be directly provided on a surface of the display module DM or on a surface of the window WP (see. FIG. 6B). FIG. 6A shows that the resin composition RC is directly provided on a surface of the display module DM. The resin composition RC having a shear viscosity of about 8 mPa·s to about 50 mPa·s at about 25° C. and at about 10 rpm, as measured in accordance with JIS Z8803 standards, may be provided (e.g., directly on the surface of the display module DM) while covering a curve of a step SP-b in the display module DM.

Referring to FIG. 6B, the window WP may be provided on the preliminary adhesive member P-AP formed by applying the resin composition RC at a uniform thickness. Then, UV-L may be provided to the preliminary adhesive member P-AP through the window WP. The preliminary adhesive member P-AP is cured to form the adhesive member AP (see FIG. 4).

In an embodiment, UV-L is directly irradiated on the preliminary adhesive member P-AP to form the adhesive member AP (see FIG. 4). Then, the window WP may be provided on the formed adhesive member AP (FIG. 4).

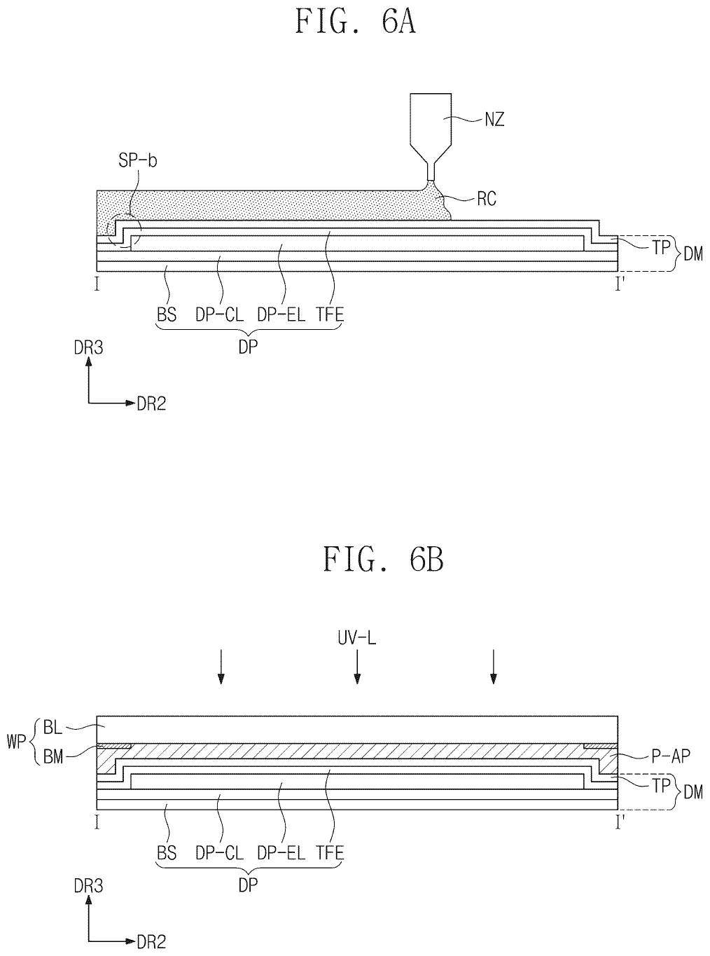

FIG. 7 is a cross-sectional view illustrating a display device DD-a according to an embodiment of the disclosure.

In the descriptions of the display device DD-a illustrated in FIG. 7, duplicated contents as the contents described with reference to FIGS. 1 to 6B will not be explained again, and a difference will be mainly described.

Comparing to the display device DD described with reference to FIGS. 3 and 4, the display device DD-a illustrated in FIG. 7 may further include an optical control layer PP and an optical adhesive layer AP-a. The optical control layer PP according to an embodiment may be arranged between an adhesive member AP and a window WP. The optical adhesive layer AP-a according to an embodiment may be arranged between the optical control layer PP and the window WP.

The optical control layer PP is arranged on the display panel DP, and thus may control reflected light on the display panel DP due to external light. The optical control layer PP may include, for example, a polarizer and/or a color filter layer.

The optical adhesive layer AP-a may be formed from the above-described resin composition RC according to an embodiment. The optical adhesive layer AP-a may include a polymer derived from the resin composition RC according to an embodiment. The optical adhesive layer AP-a including the polymer derived from the resin composition RC may have, at about 25° C., a 180° peel strength of about 800 gf/25 mm to about 2,000 gf/25 for a glass substrate or a polyethylene terephthalate (PET) film. The optical adhesive layer AP-a including a polymer derived from the resin composition RC may have, at about −20° C., a storage modulus (G′) of about 0.01 MPa to about 0.2 MPa. Therefore, the optical adhesive layer AP-a including a polymer derived from the resin composition RC according to an embodiment has high adhesion characteristics and flexibility, a lifting phenomenon does not occur at an interface of the optical adhesive layer AP-a (e.g., the adhesive layer AP-a does not detach from the adherent) even when a folding or bending operation are performed, and thus suitable or excellent adhesion reliability and folding characteristics may be obtained (e.g., exhibited).

The display device DD-a according to an embodiment may include the optical adhesive layer AP-a and the adhesive member AP, each including a polymer derived from the resin composition according to an embodiment. The display device DD-a including the optical adhesive layer AP-a and the adhesive member AP may exhibit suitable or excellent reliability during performing an operation such as folding.

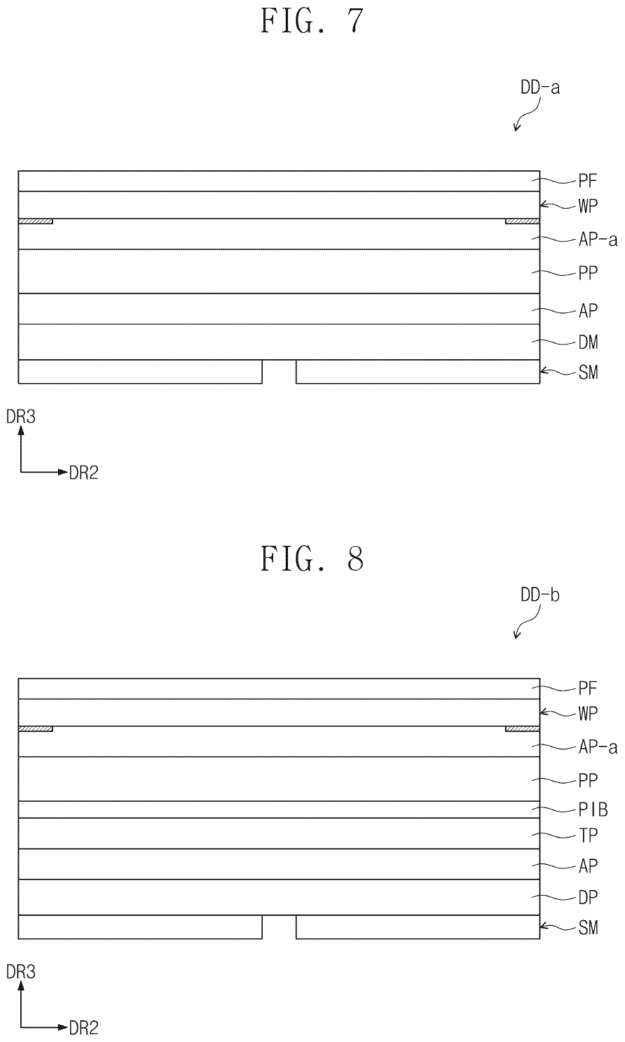

FIG. 8 is a cross-section illustrating a display device DD-b according to an embodiment of the disclosure.

In the descriptions of the display device DD-b according to an embodiment illustrated in FIG. 8, duplicated contents as the contents described with reference to FIGS. 1 to 7 will not be explained again, and a difference will be mainly described.

Comparing to the display device DD described with reference to FIGS. 3 and 4, the display device DD-b illustrated in FIG. 8 may further include an optical control layer PP, an optical adhesive layer AP-a, and an interlayer adhesive layer PIB. The optical control layer PP according to an embodiment may be arranged between an adhesive member AP and a window WP. The optical adhesive layer AP-a according to an embodiment may be arranged between the optical control layer PP and the window WP.

In the display device DD-b according to an embodiment, the adhesive member AP may be arranged between a display panel DP and an input sensing part TP. That is, the input sensing part TP may not be directly arranged on the display panel DP, and the display panel DP and the input sensing part TP may be bonded together by the adhesive member AP. For example, the adhesive member AP may be arranged between an encapsulation layer TFE (see FIG. 4) of the display panel DP and the input sensing part TP.

The interlayer adhesive layer PIB may be provided below the optical control layer PP. The interlayer adhesive layer PIB may be arranged between the input sensing part TP and the optical control layer PP and may be formed of an adhesion material having suitable or excellent moisture resistant (e.g., preventing) properties. For example, the interlayer adhesive layer PIB may include polyisobutylene. The interlayer adhesive layer PIB may be arranged on the input sensing part TP and prevent or reduce the sensing electrodes from being corroded.

The display device DD-b according to an embodiment may include the optical adhesive layer AP-a and the adhesive member AP, each including a polymer derived from the resin composition RC, and may exhibit suitable or excellent reliability during performing an operation such as folding.

Hereinafter, with reference to examples and comparative examples, an adhesive member and a display device formed from the resin composition according to an embodiment of the disclosure will be described in more detail. In addition, examples described below are only for the understanding of the disclosure, and the scope of the disclosure is not limited thereto.

### EXAMPLES

### 1. Synthesis of (Meth)Acrylate Oligomer (A)

(Meth)acrylate oligomers (A) A-1, A-2, A-3, and A-4, which were provided to resin compositions according to examples and comparative examples, were synthesized by the following methods. The (meth)acrylate oligomers (A) A-1, A-2, and A-3 are each a (meth)acrylate oligomer (A) of examples, and the (meth)acrylate oligomer (A) A-4 is a (meth)acrylate oligomer (A) of a comparative example.

In synthetic examples, a molecular weight and a molecular weight distribution were measured by using gel-permeation chromatography (GPC) analysis instrument HLC-8420GPC made by TOSHO corporation. Using TSKgel SUPER HZM-N as a measurement column, a number average molecular weight (Mn) value and a molecular weight distribution value were obtained from a size exclusion chromatography (SEC) curve detected by a refractive index (RI) detector through standard polystyrene (PS) conversion.

NMR spectrum was obtained using a nuclear magnetic resonance (NMR) analysis device AVANCE III 300M made by Bruker, and, from the obtained NMR spectrum, a copolymer composition ratio was calculated using an integration ratio of signals measured from each monomer component. In addition, in the measurement, deuterated chloroform (made by KANTO CHEMICAL CO. INC.) was used as a common solvent.

### (1) Synthesis of (Meth)Acrylate Oligomer (A) A-1

Toluene of 40 ml was added to a round flask equipped with a cooling tube, a dropping funnel, a nitrogen introduction tube, and a magnetic stirrer, and the solvent was deoxygenated by stirring for 30 minutes at room temperature while nitrogen bubbling was performed.

The obtained solvent was heated in an oil bath until internal temperature reached approximately 90° C. Next, a homogeneous solution made in advance with a siloxane monomer (FM-0711 made by JNC Corporation) of 4 g as a first polymerizable monomer, methyl methacrylate (MMA, Tokyo Kasei Kogyo Co. Ltd.) of 15.2 g, isobornyl methacrylate (IBXMA, Tokyo Chemical Industry) of 8.9 g, and 2-hydroxyethyl methacrylate (2-HEMA, Tokyo Chemical Industry) of 0.5 g as a second polymerizable monomer, V-601 (Fujifilm Wako Pure Chemical) of 1.2 g, and toluene of 10 ml as a thermal polymerization initiator, was added in a dropping funnel. The cock of the dropping funnel was opened and the homogeneous solution in the dropping funnel was slowly dripped over 1 hour into the flask, and then the mixture was stirred for 1 hour to perform a polymerization reaction.

Next, a 58 vol % ethanol aqueous solution (Fujifilm Wako Pure Chemical) of 600 ml was added in a 1000 ml beaker, stirred with a magnetic stirrer, and the solution after the polymerization reaction in the flask was added dropwise little by little thereto to obtain a precipitate. The precipitate was suction filtered, and the obtained solid was washed and filtered with a 58 vol % ethanol solution (Fujifilm Wako Pure Chemical) to remove toluene and non-reacted monomers. The precipitated product was dried under reduced pressure to obtain a white (meth)acrylate oligomer (A) A-1 powder, which is a copolymer.

(Meth)acrylate oligomer (A) A-1 has a weight average molecular weight of 10,800, and a molecular weight distribution of 1.42. A copolymer composition ratio of (meth)acrylate oligomer (A) A-1 was MMA:IBXMA: 2-EHMA:FM-0711=76.7:18.5:2.6:2.2.

### (2) Synthesis of (Meth)Acrylate Oligomer (A) A-2

In order to introduce a (meth)acrylate group at the end of (meth)acrylate oligomer (A) A-1, the following processes were performed. (Meth)acrylate oligomer (A) A-1 of 5 g, toluene of 20 ml, dibutyltin dilaurate (FUJIFILM Wako Pure Chemical) of 2.0 mg, and 2-isocyanatoethyl methacrylate (IEM) of 0.40 g were added to a round flask equipped with a cooling tube and a magnetic stirrer, and the mixture was reacted by heating in an oil bath until the internal temperature reached approximately 60° C.

Next, a 58 vol % ethanol aqueous solution (Fujifilm Wako Pure Chemical) of 600 ml was added in a 1000 ml beaker, stirred with a magnetic stirrer, and the solution after the reaction in the flask was added dropwise little by little thereto to obtain a precipitate. The precipitate was suction filtered, and the obtained solid was washed and filtered with a 58 vol % ethanol solution (Fujifilm Wako Pure Chemical) to remove a reaction solvent and non-reacted monomers. The precipitated product was dried under reduced pressure to obtain white (meth)acrylate oligomer (A) A-2 powder, which is a copolymer.

(Meth)acrylate oligomer (A) A-2 has a weight average molecular weight of 11,000, and a molecular weight distribution of 1.42. Introduction of the (meth)acrylate group was checked with the proton nuclear magnetic resonance analysis (¹H NMR). Obtained peak values of (meth)acrylate A-2 checked with ¹H NMR are as follows. Tetramethylsilane (TMS) was used as a reference material for ¹H NMR measurement, ¹H NMR was measured at a resonance frequency of 300 MHZ, and the chemical shift value was represented by δ (ppm).

A-2 ¹H NMR value (TMS, 300 MHZ) δ: 5.6 and 6.2

### (3) Synthesis of (Meth)Acrylate Oligomer (A) A-3

Toluene of 40 ml was added to a round flask equipped with a cooling tube, a dropping funnel, a nitrogen introduction tube, and a magnetic stirrer, and the solvent was deoxygenated by stirring for 30 minutes at room temperature while nitrogen bubbling was performed.

The obtained solvent was heated in an oil bath until the internal temperature reached approximately 90° C. Next, a homogeneous solution made in advance with a siloxane monomer (TM-0701T made by JNC Corporation) of 4.2 g as a first polymerizable monomer, methyl methacrylate (MMA, Tokyo Kasei Kogyo Co. Ltd.) of 15.0 g, isobornyl methacrylate (IBXMA, Tokyo Chemical Industry) of 8.9 g, and 2-hydroxyethyl methacrylate (2-HEMA, Tokyo Chemical Industry) of 0.5 g as a second polymerizable monomer, V-601 (Fujifilm Wako Pure Chemical) of 1.4 g and n-butyl acetate of 10 ml as a thermal polymerization initiator, was added in a dropping funnel. The cock of the dropping funnel was opened and the homogeneous solution in the dropping funnel was slowly dripped over 1 hour into the flask, and then the mixture was stirred for 1 hour to perform a polymerization reaction.

Next, a 58 vol % ethanol aqueous solution (Fujifilm Wako Pure Chemical) of 600 ml was added in a 1000 ml beaker, stirred with a magnetic stirrer, and the solution after the polymerization reaction in the flask was added dropwise little by little thereto to obtain a precipitate. The precipitate was suction filtered, and the obtained solid was washed and filtered with a 58 vol % ethanol solution (Fujifilm Wako Pure Chemical) to remove n-butyl acetate and non-reacted monomers. The precipitated product was dried under reduced pressure to obtain a white (meth)acrylate oligomer (A) A-3 powder, which is a copolymer.

(Meth)acrylate oligomer (A) A-3 has a weight average molecular weight of 10,800, and a molecular weight distribution of 1.42. A copolymer composition ratio of (meth)acrylate oligomer (A) A-3 was MMA:IBXMA:2-EHMA:TM-0701T=75.6:18.3:2.1:4.0.

### (4) Synthesis of (Meth)Acrylate Oligomer (A) A-4

Toluene of 40 ml was added to a round flask equipped with a cooling tube, a dropping funnel, a nitrogen introduction tube, and a magnetic stirrer, and the solvent was deoxygenated by stirring for 30 minutes at room temperature while nitrogen bubbling was performed.

The obtained solvent was heated in an oil bath until the internal temperature reaches approximately 90° C. Next, a homogeneous solution made in advance with methyl methacrylate (MMA, Tokyo Kasei Kogyo Co. Ltd.) of 14.1, isobornyl methacrylate (IBXMA, Tokyo Chemical Industry) of 11.1 g, and, as a thermal polymerization initiator, V-601 (Fujifilm Wako Pure Chemical) of 1.1 g, and n-butyl acetate of 10 ml, was added in a dropping funnel. The cock of the dropping funnel was opened and the homogeneous solution in the dropping funnel was slowly dripped over 1 hour into the flask, and then the mixture was stirred for 1 hour to perform a polymerization reaction.

Next, a 58 vol % ethanol aqueous solution (Fujifilm Wako Pure Chemical) of 600 ml was added in a 1000 ml beaker, and the mixture was stirred with a magnetic stirrer, and the solution after the polymerization reaction in the flask was added dropwise little by little thereto to obtain a precipitate. The precipitate was suction filtered, and the obtained was washed and filtered with a 58 vol % ethanol solution (Fujifilm Wako Pure Chemical) to remove toluene and non-reacted monomers. The precipitated product was dried under reduced pressure to obtain white (meth)acrylate oligomer (A) A-4 powder, which is a copolymer.

(Meth)acrylate oligomer (A) A-4 has a weight average molecular weight of 6,400, and a molecular weight distribution of 1.49. A copolymer composition ratio of (Meth)acrylate oligomer (A) A-4 was MMA:IBXMA=76.9:23.1.

### 2. Manufacturer of Resin Composition

The resin compositions according to examples were produced by mixing each material listed in Table 1. Each material in a mass (g) amount according to Tables 1 and 2 was placed in a light-shielding plastic container, and the mixture was stirred at room temperature to manufacture resin compositions according to Example 1 to Example 2, and Comparative Example 1 to Comparative Example 5.

TABLE 1

| Materials | | Example 1 | Example 2 | Example 3 | Example 4 | Example 5 |
|---|---|---|---|---|---|---|
| (Meth)acrylate | A-1 | 2 | 5 | — | — | 2 |
| oligomer (A) | A-2 | — | — | 2 | — | — |
| | A-3 | — | — | — | 2 | — |
| Photo initiator | Omnirad | 2 | 2 | 2 | 2 | 2 |
| (B) | 819 | | | | | |
| (Meth)acrylate | 4-HBA | 7 | 7 | 7 | 7 | — |
| monomer | EHDG-AT | 10 | 10 | 10 | 10 | — |
| (C) | 2-EHA | 54 | 54 | 54 | 54 | 55 |
| | THF-A | 14 | 14 | 14 | 14 | — |
| | IDAA | — | — | — | — | 30 |
| Urethane | UF-C051 | 3 | 3 | 3 | 3 | 3 |
| (meth)acrylate | UF-C052 | 3 | 3 | 3 | 3 | 3 |
| oligomer | UN6304 | 7 | 7 | 7 | 7 | 7 |
| (D) | | | | | | |

TABLE 2

| | | Comparative | Comparative | Comparative | Comparative | Comparative |
|---|---|---|---|---|---|---|
| Materials | | Example 1 | Example 2 | Example 3 | Example 4 | Example 5 |
| (Meth)acrylate | A-1 | — | — | — | — | 2 |
| oligomer | A-2 | | | | | |
| (A) | A-3 | | | | | |
| | A-4 | — | 2 | — | — | — |
| Photo | Omnirad | 2 | 2 | 2 | 2 | 2 |
| initiator | 819 | | | | | |
| (B) | | | | | | |
| (Meth)acrylate | 4-HBA | 7 | 7 | 7 | 7 | 7 |
| monomer | EHDG- | 10 | 10 | 10 | 10 | 78 |
| (C) | AT | | | | | |
| | 2-EHA | 54 | 54 | 54 | 54 | — |
| | THF-A | 14 | 14 | 14 | 14 | — |
| Urethane | UF-C051 | 3 | 3 | 3 | 3 | 3 |
| (meth)acrylate | UF-C052 | 3 | 3 | 3 | 3 | 3 |
| oligomer | UN6304 | 7 | 7 | 7 | 7 | 7 |
| (D) | | | | | | |
| Silicon- | SAG008 | — | — | 0.1 | — | — |
| based | | | | | | |
| surfactant | | | | | | |
| Fluorine- | S-656 | — | — | — | 0.1 | — |
| based | | | | | | |
| surfactant | | | | | | |

### Materials in Table 1 and Table 2

Omnirad 819: Phenylbis(2,4,6-trimethylbenzoyl) phosphine oxide (made by IGM Resins)
4-HBA: 4-hydroxybutyl acrylate (made by Osaka Organic Chemical Industry Ltd.)
EHDG-AT: 2-ethylhexyl diglycol acrylate (made by Kyoeisha Chemical Co. Ltd.)
2-EHA: 2-ethylhexyl acrylate (made by Toagosei)
THF-A: Tetrahydrofurfuryl acrylate (made by Kyoeisha Chemical Co. Ltd.)
IDAA: Isodecyl acrylate (made by Osaka Organic Chemical Industry Ltd.)
UF-C051: Urethane acrylate (weight average molecular weight: 35,000, made by Kyoeisha Chemical Co. Ltd.)
UF-C052: Urethane acrylate (weight average molecular weight: 10,000, made by Kyoeisha Chemical Co. Ltd.)
UN6304: Urethane acrylate (weight average molecular weight: 10,000 made by Negami Chemical Industrial Co. Ltd.)
SAG008: Silicon-based surfactant (weight average molecular weight: 10,000, made by Nissan Chemical Corporation)
S-656: Fluorine-based surfactant (weight average molecular weight: 10,000, made by AGC SEIMI CHEMICAL)

### 3. Manufacture of Adhesive Member (Test Specimen)

Each of the above-described resin composition was applied on a soda-lime glass (Central Glass Co. Ltd.) by an inkjet printer (made by MicroJet Technology Co. Ltd.) to have a thickness of about 50 μm.

Under the presence of oxygen, UV was irradiated to the soda-lime glass, on which the resin composition was applied, using UV led lamps having a peak wavelength of about 405 nm and about 365 nm respectively, such that accumulated light doses (e.g., amounts) were about 220 mJ/cm² and about 380 mJ/cm², respectively.

A polyethylene terephthalate (PET) film (TOYOBO CO. LTD., product name A4360, thickness 50 μm) cut to about 20 mm×150 mm in advance was joined to the soda-lime glass irradiated with UV at a joining pressure of 0.15 MPa. Then, UV was irradiated using a UV lamp having a peak wavelength of about 396 nm such that an accumulated light dose (e.g., amount) was about 4,000 mJ/cm² to obtain a specimen.

### 4. Evaluation of Characteristics of Resin Composition and Adhesive Member

A surface tension of (meth)acrylate monomer (C) in each of the resin compositions according to examples and comparative examples, a shear viscosity of each resin composition, and a peel strength of the adhesive member including the same were evaluated, and the results were listed in Table 2 below.

### (Surface Tension Evaluation of (Meth)Acrylate Monomer (C) in Resin Composition)

The surface tension of the (meth)acrylate monomer (C) in each of the resin compositions was measured by a pendant drop method using a contact angle meter (Kyowa Interface Science Co., Ltd. DMo-601).

### (Shear Viscosity Evaluation of Resin Composition)

The shear viscosity of each resin composition was measured in accordance with JIS Z8803 standards at 25° C. The shear viscosity of each resin composition was measured at a speed of 20 rpm using a viscometer TVE-25L (made by TOKISANGYO).

### (Spread Wettability Evaluation of Resin Composition)

A spread wettability of each resin composition was measured in the following manner. 2 μL droplets were dropped on a PET film (TOYOBO CO. LTD. product name A4360, thickness of 50 μm). Next, the droplets were observed after 60 seconds, and the droplets that maintained a circular shape were marked with an O, and the droplets that did not maintain the shape were marked with an X.

### (Peel Strength Evaluation of Adhesive Member)

For evaluating peel strength of the adhesive member, the specimen was tested at 25° C. using a peeling angle of 180° and at a speed of 300 mm/min, and the peel strength was measured by using a universal testing machine (Instron Corporation, product type 5965). An average peel strength value of about 50 mm peeling was calculated, and the average value was multiplied by 1.25 to evaluate the peeling strength for a width of 25 mm.

TABLE 3

| | | | | | | | Compar- | Compar- | Compar- | Compar- | Compar- |
|---|---|---|---|---|---|---|---|---|---|---|---|
| | | Example | Example | Example | Example | Example | ative | ative | ative | ative | ative |
| Material | | 1 | 2 | 3 | 4 | 5 | Example 1 | Example 2 | Example 3 | Example 4 | Example 5 |
| Surface | 4- | 36 | 36 | 36 | — | 36 | 36 | 36 | 36 | 36 | 36 |
| tension of | HBA | | | | | | | | | | |
| (meth)acrylate | EHDG- | 37 | 37 | 37 | — | 37 | 37 | 37 | 37 | 37 | 37 |
| monomer | AT | | | | | | | | | | |
| (C) | 2- | 26 | 26 | 26 | 26 | 26 | 26 | 26 | 26 | 26 | — |
| [mN/m] | EHA | | | | | | | | | | |
| | THF- | 35 | 35 | 35 | — | 35 | 35 | 35 | 35 | 35 | — |
| | A | | | | | | | | | | |
| | IDAA | — | — | — | 28 | — | — | — | — | — | |

| | | | | | | | | | | |
|---|---|---|---|---|---|---|---|---|---|---|
| Shear viscosity at | 17 | 20 | 17 | 17 | 16 | 15 | 16 | 15 | 15 | 60 |
| 25° C. | | | | | | | | | | |
| [mPa · s] | | | | | | | | | | |
| Spread wettability | ◯ | ◯ | ◯ | ◯ | ◯ | X | X | ◯ | ◯ | X |
| 180° peel strength | 1200 | 1350 | 1300 | 1250 | 900 | 900 | 1250 | 400 | 100 | 150 |
| [gf/25 mm] | | | | | | | | | | |

Referring to Table 1 and Table 3, the resin compositions according to Example 1 to Example 5 include A-1, A-2, or A-3, as a (meth)acrylate oligomer (A) according to the disclosure. Each of the resin compositions according to Example 1 to Example 5 includes the (meth)acrylate oligomer (A) including a siloxane skeleton. In addition, each of the resin compositions according to Example 1 to Example 5 includes the (meth)acrylate monomer (C) of the disclosure, and includes a first monomer having a surface tension of about 20 mN/m to about 30 mN/m. The resin compositions according to Example 1 to Example 5 have a shear viscosity at 25° C. of about 8 mPa·s to about 50 mPa·s. On the contrary, referring to Table 2 and Table 3, the resin compositions according to Comparative Examples 1, 3, and 4 include no (meth)acrylate oligomer (A). The resin composition according to Comparative Example 2 includes A-4 that does not correspond to embodiments of the disclosure as a (meth)acrylate oligomer (A). A-4 contained in the resin composition according to Comparative Example 2 includes no siloxane skeleton. In addition, the resin composition according to Comparative Example 5 includes A-1, which is the (meth)acrylate oligomer (A) including a siloxane skeleton, according to the disclosure, but does not include the (meth)acrylate oligomer (C) according to the disclosure. The resin composition according to Comparative Example 5 includes no first monomer having a surface tension of about 20 mN/m to about 30 mN/m, and includes only a (meth)acrylate monomer having a surface tension of more than about 30 mN/m. The resin composition according to Comparative Example 5 has a shear viscosity at 25° C. of more than about 50 mPa·s.

Referring to Table 1 to Table 3, in cases of Example 1 to Example 5, it can be confirmed that, suitable or excellent discharging properties, high application and adhesion reliability on glass substrates, and/or the like are obtained (or shown) when an ink from the resin composition including the above-described material combinations is provided. Therefore, when the adhesive member that is applied to a flexible display device is formed from the resin composition according to examples, durability and folding characteristics thereof may be improved.

It can be seen that resin compositions according to Example 1 to Example 5 each have a shear viscosity at 25° C. of about 8 mPa·s to about 50 mPa·s, as measured in accordance with JIS Z8803 standards. Therefore, when the resin composition according to an embodiment of the disclosure is provided by an inkjet printing method, the resin composition may be stably discharged, and may be applied at a uniform thickness.

It can be seen that the adhesive members formed from the resin compositions according to each of Example 1 to Example 5 have 180° peel strengths of about 800 gf/25 mm to about 2,000 gf/25 mm. Therefore, the adhesive member including the resin composition according to an embodiment of the disclosure may have suitable or excellent adhesion reliability.

It can be seen that each of the (meth)acrylate monomers (C) in the resin compositions according to Example 1 to Example 5 has a surface tension of about 20 mN/m to about 30 mN/m. It can be seen that spread wettability of the resin compositions according to each of Example 1 to Example 5 is marked as O. Therefore, when the resin composition according to an embodiment of the disclosure is provided on a glass substrate, a PET film, and/or the like by an inkjet printing method, the resin composition according to an embodiment may be applied at a uniform thickness without deteriorating an application shape while maintaining suitable or excellent adhesion reliability at the same time.

On the contrary, the resin composition according to Comparative Example 1 does not include the (meth)acrylate oligomer (A), and in a case of the resin composition according to Comparative Example 2, the (meth)acrylate oligomer (A) does not include a siloxane skeleton. It can be seen that spread wettability of each of the resin compositions according to Comparative Example 1 and Comparative Example 2 is marked as X. It can be determined that the resin compositions according to Comparative Example 1 and Comparative Example 2 do not include a (meth)acrylate oligomer (A), or the (meth)acrylate oligomer (A) does not include a siloxane skeleton, and thus when the resin compositions are provided on a glass substrate, a PET film, and/or the like by an inkjet printing method, the application uniformity (e.g., uniformity of the deposited layer) decreases.

The resin compositions according to Comparative Example 3 and Comparative Example 4 do not include a (meth)acrylate oligomer (A), but include a surfactant. It can be seen that the resin compositions according to Comparative Example 3 and Comparative Example 4 have the spread wettability marked as O, and the adhesive members formed from the resin compositions according to Comparative Example 3 and Comparative Example 4 have 180° peel strengths at 25° C. of less than about 800 gf/25 mm. The resin compositions according to Comparative Example 3 and Comparative Example 4 include a surfactant, and thus the resin compositions may be applied at a uniform thickness when being provided by an inkjet printing method on a glass substrate, a PET film, and/or the like. However, it can be determined that the adhesive members formed from the resin compositions according to Comparative Example 3 and Comparative Example 4 do not include the (meth)acrylate oligomer (A) having a siloxane skeleton, and thus have low adhesion.

The resin composition according to Comparative Example 5 includes a (meth)acrylate oligomer (A) having a siloxane skeleton, but does not include a first monomer having a surface tension of about 20 mN/m to about 30 mN/m. In addition, the resin composition according to Comparative Example 5 has a shear viscosity at 25° C. of more than about 50 mPa·s. Therefore, it can be seen that the resin composition according to Comparative Example 5 has spread wettability that is marked as X, and the adhesive member formed from the resin composition according to Comparative Example 5 has a 180° peel strength at 25° C. of less than about 800 gf/25 mm. It is determined that the resin composition according to Comparative Example 5 include no (meth)acrylate monomer (C) including a first monomer, and thus application uniformity (e.g., the uniformity of the deposited adhesive layer) decreases when the resin composition is provided by an inkjet printing method on a glass substrate, a PET film, and/or the like. In addition, it is determined that the resin composition according to Comparative Example 5 has a shear viscosity at 25° C. of more than about 50 mPa·s, which makes the resin composition difficult to be discharged and makes the adhesive member including the resin composition have reduced adhesion reliability.

The resin composition according to an embodiment of the disclosure may include at least one (meth)acrylate oligomer (A) including a siloxane skeleton, at least one photo initiator (B), at least one (meth)acrylate monomer (C) having a surface tension of about 20 mN/m to about 30 mN/m, and at least one urethane (meth)acrylate oligomer (D). The resin composition according to an embodiment of the disclosure may have a shear viscosity at 25° C. of about 8 mPa·s to about 50 mPa·s, as measured in accordance with JIS Z8803 standards. Therefore, the resin composition according to an embodiment may exhibit suitable or excellent discharging stability, and the adhesive member formed from the resin composition according to an embodiment may exhibit suitable or excellent application uniformity while maintaining suitable or excellent adhesiveness at the same time. The display device according to an embodiment of the disclosure may include the adhesive member arranged between the display panel and the window. The adhesive member may include a polymer derived from the resin composition according to an embodiment. Therefore, the display device including the adhesive member according to an embodiment may exhibit suitable or excellent adhesion reliability even when performing an operation such as folding/unfolding.

According to foregoing, the resin composition according to the disclosure may have suitable or excellent discharge stability, application uniformity and adhesive strength.

In addition, the display device according to disclosure includes the adhesive member having a suitable or excellent adhesive strength, and thus may have suitable or excellent reliability in various operation states. In other words, the resin composition described in this disclosure includes specific (meth)acrylate oligomer(s), photo initiator(s), and (meth)acrylate monomer(s), resulting in excellent discharge stability and adhesive strength. With a shear viscosity of about 8 mPa·s to about 50 mPa·s at 25° C., it ensures uniform application and strong adhesion. The display device, featuring an adhesive member derived from this resin, maintains high reliability and adhesion even during operations like folding and unfolding, making it suitable for various operational states.

As used herein, the term “and/or” includes any and all combinations of one or more of the associated listed items. Throughout the disclosure, the expression “at least one of a, b and c”, “at least one of a, b or c”, “at least one selected from a, b, and c”, “at least one selected from the group consisting of a, b, and c”, “at least one from among a, b, and c”, “at least one of a to c”, etc., indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively. The use of “may” when describing embodiments of the inventive concept refers to “one or more embodiments of the inventive concept.”

In present disclosure and unless otherwise defined, “not including a or any ‘component’” “excluding a or any ‘component’”, “‘component’-free”, and/or the like refers to that the “component” not being added, selected or utilized as a component in the formula/composition/structure, but the “component” of less than a suitable amount may still be included due to other impurities and/or external factors.

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display manufacturing device, a display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hitherto, although certain embodiments of the present disclosure have been described, it should be understood that the present invention should not be limited to these embodiments, but various suitable changes and modifications can be made by one ordinary skilled in the art within the spirit and scope of the present disclosure as hereinafter claimed, and equivalents thereof.

Therefore, the technical scope of the disclosure is not intended to be limited to the contents set forth in the detailed description of the specification, but is intended to be defined by the appended claims, and equivalents thereof.

What is claimed is:

1. A display device comprising:
a display panel;
a window on the display panel; and
an adhesive member between the display panel and the window,
wherein the adhesive member is derived from a resin composition,
wherein the resin composition comprises:
a (meth)acrylate oligomer (A) comprising a siloxane skeleton;
a photo initiator (B);
a (meth)acrylate monomer (C) comprising a first monomer that has a surface tension of about 20 mN/m to about 30 mN/m and is represented by Formula 1; and
an urethan (meth)acrylate oligomer (D), and
wherein the resin composition has, at about 25° C., a shear viscosity of about 8 mPa·s to about 50 mPa·s: 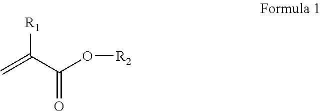
where, in Formula 1,
R₁ is a hydrogen atom, or a substituted or unsubstituted methyl group, and
R₂ is a substituted or unsubstituted alkyl group having 1 to 20 carbons.

2. The display device of claim 1, wherein the (meth)acrylate oligomer (A) is synthesized from a first polymerizable monomer represented by Formula 2-1 or Formula 2-2: 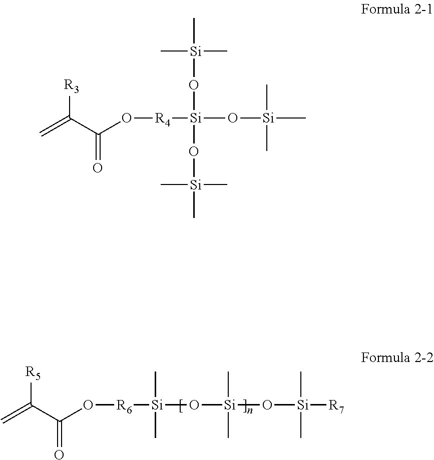
where, in Formula 2-1 and Formula 2-2,
R₃ and R₅ are each independently a hydrogen atom, or a substituted or unsubstituted methyl group,
R₄ and R₆ are each independently a substituted or unsubstituted alkylene group having 1 to 20 carbons,
R₇ is a substituted or unsubstituted alkyl group having 1 to 20 carbons, and
n is an integer of 0 to 20.

3. The display device of claim 2, wherein, in Formula 2-1:
R₃ is an unsubstituted methyl group; and
R₄ is an unsubstituted n-propylene group.

4. The display device of claim 2, wherein, in Formula 2-2:
R₅ is an unsubstituted methyl group;
R₆ is an unsubstituted n-propylene group; and
R₇ is an unsubstituted n-butyl group.

5. The display device of claim 2, wherein:
the (meth)acrylate oligomer (A) is synthesized from the first polymerizable monomer and a second polymerizable monomer different from the first polymerizable monomer; and
the second polymerizable monomer comprises at least one selected from among methyl methacrylate, isobornyl methacrylate, and 2-hydroxyethyl methacrylate.

6. The display device of claim 1, wherein the first monomer comprises 2-ethylhexyl acrylate or isodecyl acrylate.

7. The display device of claim 6, wherein:
the (meth)acrylate monomer (C) further comprises a second monomer different from the first monomer; and
the second monomer comprises at least one selected from among 4-hydroxybutyl acrylate, tetrahydrofurfuryl acrylate, and 2-ethylhexyl diglycol acrylate.

8. The display device of claim 1, wherein the resin composition is a solvent-free composition.

9. The display device of claim 1, wherein the (meth)acrylate oligomer (A) has a weight average molecular weight of about 4,000 to about 20,000.

10. The display device of claim 1, wherein the (meth)acrylate monomer (C) has a weight average molecular weight of about 400 to about 1,500.

11. The display device of claim 1, wherein the urethane (meth)acrylate oligomer (D) has a weight average molecular weight of about 8,000 to about 50,000.

12. The display device of claim 1, wherein, based on a total 100 weight percent (100 wt %) of the resin composition:
the (meth)acrylate oligomer (A) is about 1 wt % to about 7 wt % in amount;
the photo initiator (B) is about 1 wt % to about 5 wt % in amount;
the (meth)acrylate monomer (C) is about 50 wt % to about 90 wt % in amount; and
the urethane (meth)acrylate oligomer (D) is about 1 wt % to about 15 wt % in amount.

13. The display device of claim 1, wherein the photo initiator (B) comprises a radical polymerizable initiator.

14. The display device of claim 1, wherein the adhesive member has, at −20° C., a storage modulus of about 0.2 MPa or less.

15. The display device of claim 1, wherein the adhesive member has, at about 25° C., a 180° peel strength of about 800 gf/25 mm or greater for a glass substrate or a polyethylene terephthalate (PET) film.

16. The display device of claim 1, wherein the adhesive member is formed by directly depositing the resin composition onto a surface of the window or a surface of the display panel and then UV curing the resin composition.

17. The display device of claim 1, further comprising an input sensing part, wherein the adhesive member is between the display panel and the input sensing part or between the input sensing part and the window.

18. The display device of claim 17,
wherein the display panel comprises a display element layer and an encapsulation layer on the display element layer,
the input sensing part is directly on the encapsulation layer, and
the adhesive member is on the input sensing part.

19. The display device of claim 1, further comprising:
an optical control layer between the adhesive member and the window; and
an optical adhesive layer between the optical control layer and the window,
wherein the optical adhesive layer comprises a polymer derived from the resin composition.

20. The display device of claim 1, wherein
the display device comprises at least one folding axis, and
at least a portion of the display device is folded with respect to the folding axis.

21. A resin composition comprising:
a (meth)acrylate oligomer (A) comprising a siloxane skeleton;
a photo initiator (B);
a (meth)acrylate monomer (C) comprising a first monomer which has a surface tension of about 20 mN/m to about 30 mN/m and is represented by Formula 1; and
an urethane (meth)acrylate oligomer (D),
wherein the resin composition has a shear viscosity at 25° C. of about 8 mPa·s to 50 mPa·s: 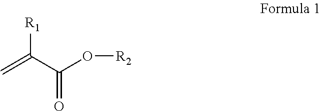
where, in Formula 1,
R₁ is a hydrogen atom, or a substituted or unsubstituted methyl group, and
R₂ is a substituted or unsubstituted alkyl group having 1 to 20 carbons.
